(19) United States
(12) Patent Application Publication
(10) Pub. No.: US 2018/0234075 A1
(43) Pub. Date: Aug. 16, 2018

(54) BULK ACOUSTIC WAVE RESONATOR

(71) Applicant: Samsung Electro-Mechanics Co., Ltd., Suwon-si (KR)

(72) Inventors: Tae Hun Lee, Suwon-si (KR); Dae Hun Jeong, Suwon-si (KR); Chang Hyun Lim, Suwon-si (KR); Tae Yoon Kim, Suwon-si (KR); Moon Chul Lee, Suwon-si (KR)

(73) Assignee: Samsung Electro-Mechanics Co., Ltd., Suwon-si (KR)

(21) Appl. No.: 15/809,545

(22) Filed: Nov. 10, 2017

(30) Foreign Application Priority Data
Feb. 14, 2017 (KR) 10-2017-0020159
May 23, 2017 (KR) 10-2017-0063577

(51) Int. Cl. H03H 9/02; H01L 41/047; H03H 9/17; H03H 9/13

(52) U.S. Cl. CPC H03H 9/02086; H01L 41/0475; H03H 9/132; H03H 9/17; H01L 41/0472

(57) ABSTRACT

A bulk acoustic wave resonator includes: a substrate; a lower electrode connecting member disposed on the substrate; a resonating member including a lower electrode disposed on the lower electrode connecting member, a piezoelectric layer disposed on the lower electrode, and an upper electrode disposed on the piezoelectric layer; and an upper electrode connecting member electrically connecting the upper electrode and the substrate to each other. The upper electrode connecting member is extended from the substrate outside of the resonating member and is connected to a top surface of the upper electrode. The lower electrode connecting member electrically connects the lower electrode and the substrate to each other and includes a ring shape corresponding to a shape of the resonating member so as to support an edge of the resonating member.

### CROSS-REFERENCE TO RELATED APPLICATIONS

This application claims benefit under 35 U.S.C. § 119(a) of Korean Patent Application Nos. 10-2017-0020159 and 10-2017-0063577 filed on Feb. 14, 2017 and May 23, 2017, respectively, in the Korean Intellectual Property Office, the entire disclosures of which are incorporated herein by reference for all purposes.

### BACKGROUND

### 1. Field

The following description relates to a bulk acoustic wave resonator.

### 2. Description of Related Art

As bandwidth use is increasing, communications companies continuously require high performance and stabilization of element characteristics, in addition to miniaturization, when manufacturing a bulk acoustic wave resonator and a microelectromechanical system (MEMS) element.

In particular, as the types of bands within overall bandwidth are increasingly used, band gaps between bands should be gradually reduced.

In addition, since such a phenomenon causes intraband and interband gaps to be narrowed, the need for interference prevention is emerging.

In order to improve characteristics as described above, there is a need to improve insertion loss, significantly reduce interband interference, and suppress an occurrence of an intraband notch.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In one general aspect, a bulk acoustic wave resonator includes: a substrate; a lower electrode connecting member disposed on the substrate; a resonating member including a lower electrode disposed on the lower electrode connecting member, a piezoelectric layer disposed on the lower electrode, and an upper electrode disposed on the piezoelectric layer; and an upper electrode connecting member electrically connecting the upper electrode and the substrate to each other. The upper electrode connecting member is extended from the substrate outside of the resonating member and is connected to a top surface of the upper electrode. The lower electrode connecting member electrically connects the lower electrode and the substrate to each other and includes a ring shape corresponding to a shape of the resonating member so as to support an edge of the resonating member.

The lower electrode connecting member may be connected to a bottom surface of the lower electrode.

The upper electrode connecting member may include an anchor member disposed on the substrate, a plate member extended from the anchor member, and a connecting part disposed on the top surface of the upper electrode and connected to the plate member.

The connecting part may be disposed on a portion of a region of an edge of the upper electrode.

The connecting part may be disposed on an entire region of an edge of the upper electrode.

The upper electrode may have a size that is smaller than a size of the piezoelectric layer. The connecting part may be connected to a portion of a region of an edge of the upper electrode and may have the ring shape corresponding to the shape of the resonating member.

The bulk acoustic wave resonator may further include: a reflective layer disposed on a top surface of the substrate, wherein the lower electrode connecting member and the upper electrode connecting member are disposed on the reflective layer.

The bulk acoustic wave resonator may further include a membrane layer covering a cavity.

In another general aspect, a bulk acoustic wave resonator includes: a substrate; a lower electrode connecting member disposed on the substrate; a resonating member including a lower electrode disposed on the lower electrode connecting member; a piezoelectric layer disposed on the lower electrode, and an upper electrode disposed on the piezoelectric layer; and an upper electrode connecting member electrically connecting the upper electrode and the substrate to each other. The lower electrode connecting member electrically connects the lower electrode and the substrate to each other and forms a cavity between the resonating member and the substrate. The lower electrode connecting member supports a central portion of the resonating member. The upper electrode connecting member is extended from the substrate outside of the resonating member and is connected to a top surface of the upper electrode.

The lower electrode connecting member may include a base part disposed on the substrate, and a support part extended from the base part and connected to a bottom surface of the lower electrode.

The lower electrode may be disposed on a central part of the piezoelectric layer.

The upper electrode connecting member may be connected to a central portion of the upper electrode.

In another general aspect, a bulk acoustic wave resonator includes: a substrate; a lower electrode connecting member disposed on the substrate; a resonating member including a lower electrode disposed on the lower electrode connecting member, a piezoelectric layer disposed on the lower electrode, and an upper electrode disposed on the piezoelectric layer; and an upper electrode connecting member electrically connecting the upper electrode and the substrate to each other. The lower electrode connecting member electrically connects the substrate and the lower electrode to each other and supports a portion of an edge of the resonating member. The upper electrode connecting member is spaced apart from the lower electrode connecting member and supports another portion of the edge of the resonating member. The lower electrode connecting member and the upper electrode connecting member form a cavity between the resonating member and the substrate.

The upper electrode may include a connecting part connected to the upper electrode connecting member.

The bulk acoustic wave resonator may further include a membrane layer formed to cover a cavity.

In another general aspect, a bulk acoustic wave resonator includes: a substrate; a lower electrode connecting member disposed on the substrate; a first resonating member disposed on the lower electrode connecting member; a resonating member connecting member connected to the first resonating member; a second resonating member connected to the first resonating member through the resonating member connecting member, and disposed on the first resonating member; and an upper electrode connecting member electrically connecting the substrate and the second resonating member to each other.

The first lower electrode may be disposed on a first membrane layer. The lower electrode connecting member may form a first cavity together with the first membrane layer and the substrate.

The second lower electrode may be disposed on a second membrane layer. The resonating member connecting member may form a second cavity together with the second membrane layer.

Other features and aspects will be apparent from the following detailed description, the drawings, and the claims.

### BRIEF DESCRIPTION OF DRAWINGS

FIG. 1 is a schematic configuration view illustrating a bulk acoustic wave resonator, according to an embodiment.

FIG. 2 is a schematic configuration view illustrating a bulk acoustic wave resonator, according to another embodiment.

FIG. 3 is a schematic configuration view illustrating a bulk acoustic wave resonator, according to another embodiment.

FIG. 4 is a schematic configuration view illustrating a bulk acoustic wave resonator, according to another embodiment.

FIG. 5 is a schematic configuration view illustrating a bulk acoustic wave resonator, according to another embodiment.

FIG. 6 is a schematic configuration view illustrating a bulk acoustic wave resonator, according to another embodiment.

FIG. 7 is a schematic configuration view illustrating a bulk acoustic wave resonator, according to another embodiment.

FIG. 8 is a schematic configuration view illustrating a bulk acoustic wave resonator, according to another embodiment.

FIG. 9 is a schematic configuration view illustrating a bulk acoustic wave resonator, according to another embodiment.

FIG. 10 is a schematic configuration view illustrating a bulk acoustic wave resonator, according to another embodiment.

FIG. 11 is a schematic configuration view illustrating a bulk acoustic wave resonator, according to another embodiment.

FIG. 12 is a schematic configuration view illustrating a filter device, according to an embodiment.

FIGS. 13 through 22 are process flowcharts illustrating a method for manufacturing a bulk acoustic wave resonator, according to an embodiment.

Throughout the drawings and the detailed description, the same reference numerals refer to the same elements. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of the disclosure of this application. For example, the sequences of operations described herein are merely examples, and are not limited to those set forth herein, but may be changed as will be apparent after an understanding of the disclosure of this application, with the exception of operations necessarily occurring in a certain order. Also, descriptions of features that are known in the art may be omitted for increased clarity and conciseness.

The features described herein may be embodied in different forms, and are not to be construed as being limited to the examples described herein. Rather, the examples described herein have been provided merely to illustrate some of the many possible ways of implementing the methods, apparatuses, and/or systems described herein that will be apparent after an understanding of the disclosure of this application.

Throughout the specification, when an element, such as a layer, region, or substrate, is described as being “on,” “connected to,” “coupled to,” “over,” or “covering” another element, it may be directly “on,” “connected to,” “coupled to,” “over,” or “covering” the other element, or there may be one or more other elements intervening therebetween. In contrast, when an element is described as being “directly on,” “directly connected to,” “directly coupled to,” “directly over,” or “directly covering” another element, there can be no other elements intervening therebetween.

As used herein, the term “and/or” includes any one and any combination of any two or more of the associated listed items.

Although terms such as “first,” “second,” and “third” may be used herein to describe various members, components, regions, layers, or sections, these members, components, regions, layers, or sections are not to be limited by these terms. Rather, these terms are only used to distinguish one member, component, region, layer, or section from another member, component, region, layer, or section. Thus, a first member, component, region, layer, or section referred to in examples described herein may also be referred to as a second member, component, region, layer, or section without departing from the teachings of the examples.

Spatially relative terms such as “above,” “upper,” “below,” and “lower” may be used herein for ease of description to describe one element's relationship to another element as shown in the figures. Such spatially relative terms are intended to encompass different orientations of the device in use or operation in addition to the orientation depicted in the figures. For example, if the device in the figures is turned over, an element described as being “above” or “upper” relative to another element will then be “below” or “lower” relative to the other element. Thus, the term “above” encompasses both the above and below orientations depending on the spatial orientation of the device. The device may also be oriented in other ways (for example, rotated 90 degrees or at other orientations), and the spatially relative terms used herein are to be interpreted accordingly.

The terminology used herein is for describing various examples only, and is not to be used to limit the disclosure. The articles “a,” “an,” and “the” are intended to include the plural forms as well, unless the context clearly indicates otherwise. The terms “comprises,” “includes,” and “has” specify the presence of stated features, numbers, operations, members, elements, and/or combinations thereof, but do not preclude the presence or addition of one or more other features, numbers, operations, members, elements, and/or combinations thereof.

Due to manufacturing techniques and/or tolerances, variations of the shapes shown in the drawings may occur. Thus, the examples described herein are not limited to the specific shapes shown in the drawings, but include changes in shape that occur during manufacturing.

The features of the examples described herein may be combined in various ways as will be apparent after an understanding of the disclosure of this application. Further, although the examples described herein have a variety of configurations, other configurations are possible as will be apparent after an understanding of the disclosure of this application.

Hereinafter, embodiments will be described in detail with reference to the accompanying drawings.

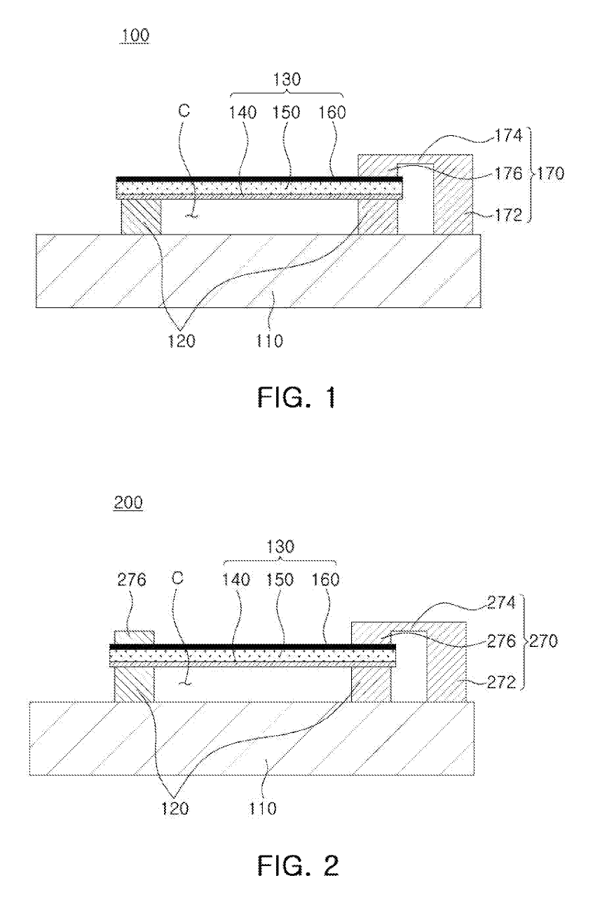

FIG. 1 is a schematic configuration view illustrating a bulk acoustic wave resonator 100, according to an embodiment.

Referring to FIG. 1, the bulk acoustic wave resonator 100 includes, for example, a substrate 110, lower electrode connecting members 120, a resonating member 130, and an upper electrode connecting member 170.

The substrate 110 may be a substrate on which silicon is stacked. For example, a silicon wafer is used as the substrate 110. A substrate protective layer (not shown) may be formed on the substrate 110.

The lower electrode connecting members 120 are formed on the substrate 110 and form a cavity C together with the resonating member 130. The lower electrode connecting members 120 are disposed to support edges of the resonating member 130. As an example, the lower electrode connecting members 120 has an amorphous ring shape corresponding to a shape of the resonating member 130.

Accordingly, since the lower electrode connecting members 120 support the entire region of the edges of the resonating member 130, structural robustness of the bulk acoustic wave resonator 100 is provided.

The lower electrode connecting members 120 electrically connect a lower electrode 140 of the resonating member 130, to be described below, to the substrate 110. The lower electrode connecting members 120 are formed of a conductive material such as copper (Cu) or tungsten (W).

As such, since the lower electrode connecting members 120 support the entire region of the edges of the resonating member 130, resistance of an electrode connecting part may be reduced and heat radiation may be improved. As a result, insertion loss due to electrical loss may be reduced and interband notch failures, which may be caused by a temperature difference due to a difference in consumed power between bulk acoustic wave resonators 100 in a filter device, may also be controlled.

The resonating member 130 is disposed on the lower electrode connecting members 120. As an example, the resonating member 130 includes a lower electrode 140, a piezoelectric layer 150, and an upper electrode 160.

The lower electrode 140 forms the cavity C together with the lower electrode connecting members 120 and is disposed so that edges of the lower electrode 140 are supported by the lower electrode connecting members 120. As an example, the lower electrode 140 is formed of a conductive material such as molybdenum (Mo), ruthenium (Ru), tungsten (W), iridium (Ir), or platinum (Pt), or alloys thereof.

In addition, the lower electrode 140 may be used as either one of an input electrode that inputs an electrical signal such as a radio frequency (RF) signal, and an output electrode. For example, in a case in which the lower electrode 140 is the input electrode, the upper electrode 160 is the output electrode, and in a case in which the lower electrode 140 is the output electrode, the upper electrode 160 is the input electrode.

Although the embodiment of FIG. 1 describes a case in which the lower electrode 140 is formed on the lower electrode connecting members 120, the lower electrode 140 is not limited to such a configuration. For example, a membrane layer and/or a seed layer may be formed below the lower electrode 140. That is, the membrane layer and/or the seed layer may be formed on the lower electrode connecting members 120 and the lower electrode 140 may be then formed on the membrane layer and/or the seed layer.

The piezoelectric layer 150 is formed on the lower electrode 140. As an example, the piezoelectric layer 150 is formed by depositing aluminum nitride, doped aluminum nitride, zinc oxide, or lead zirconate titanate.

In addition, the piezoelectric layer 150, when formed of aluminum nitride (AlN), may further include a rare earth metal. As an example, the rare earth metal includes any one or any combination of any two or more of scandium (Sc), erbium (Er), yttrium (Y), and lanthanum (La). In addition, the piezoelectric layer 150, when formed of aluminum nitride (AlN), may further include a transition metal. As an example, the transition metal includes any one or any combination of any two or more of zirconium (Zr), titanium (Ti), magnesium (Mg), and hafnium (Hf).

The upper electrode 160 is formed on the piezoelectric layer 150. As an example, the upper electrode 160 is also formed of a conductive material such as molybdenum (Mo), ruthenium (Ru), tungsten (W), iridium (Ir), or platinum (Pt), or alloys thereof, similarly to the lower electrode 140.

The upper electrode connecting member 170 is formed on the substrate 110 and one end portion of the upper electrode connecting member 170 is connected to the upper electrode 160. As an example, the upper electrode connecting member 170 includes an anchor member 172 formed on the substrate 110, a plate member 174 extended from the anchor member 172 to be parallel to a top surface of the substrate 110, and a connecting part 176 formed on a portion of an edge of a top surface of the upper electrode 160 and connected to the plate member 174.

In addition, the anchor member 172 is formed on the substrate 110 so as to be spaced apart from the lower electrode connecting members 120. In other words, the anchor member 172 is spaced apart from the lower electrode connecting members 140 on the substrate 110.

The connecting part 176 may be connected to only one region of the edge of the upper electrode 160. As an example, the upper electrode connecting member 170 is formed of a conductive material such as copper (Cu) or tungsten (W), similarly to the lower electrode connecting members 120.

As described above, since the lower electrode 140 and the upper electrode 160 are connected to the substrate 110 through the lower electrode connecting members 120 and the upper electrode connecting member 170, respectively, a gap between bulk acoustic wave resonators 100 in a filter device may be reduced, and, therefore, a size of the filter device may also be reduced.

Further, since the lower electrode connecting members 120 are disposed to support the entire region of the edge of the resonating member 130, the entire region except for a release hole for forming the cavity C may be used as a support layer, thereby providing the structural robustness.

In addition, since resistance of the electrode connecting part is reduced and heat radiation is improved, insertion loss by the electrical loss may be reduced, and the interband notch failure which may be caused by a temperature difference due to a difference in power consumption between bulk acoustic wave resonators 100 in a filter device may also be controlled.

FIG. 2 is a schematic configuration view illustrating a bulk acoustic wave resonator 200, according to another embodiment.

Referring to FIG. 2, the bulk acoustic wave resonator 200 includes, for example, the substrate 110, the lower electrode connecting members 120, the resonating member 130, and an upper electrode connecting member 270.

Since the substrate 110, the lower electrode connecting members 120, and the resonating member 130 are the same components as the corresponding components included in the bulk acoustic wave resonator 100, a detailed description of the substrate 110, the lower electrode connecting members 120, and the resonating member 130 will be omitted and will be replaced with the description above.

The upper electrode connecting member 270 is formed on the substrate 110 and one end portion of the upper electrode connecting member 270 is connected to the upper electrode 160. As an example, the upper electrode connecting member 270 includes an anchor member 272 formed on the substrate 110, a plate member 274 extended from the anchor member 272 to be parallel to a top surface of the substrate 110, and a connecting part 276 formed on a top surface of the upper electrode 160 and connected to an end of the plate member 274.

The connecting part 276 is connected to an edge of the upper electrode 160. As an example, the connecting part 276 has a shape corresponding to a shape of the resonating member 130, and has, for example, an amorphous ring shape.

The upper electrode connecting member 270 is formed of a conductive material such as copper (Cu) or tungsten (W), similarly to the lower electrode connecting members 120.

As described above, since the lower electrode 140 and the upper electrode 160 are connected to the substrate 110 through the lower electrode connecting members 120 and the upper electrode connecting member 270, respectively, a gap between bulk acoustic wave resonators 200 in a filter device may be reduced, and, therefore, a size of the filter device may also be reduced.

Further, since the lower electrode connecting members 120 are disposed to support the entire region of the edge of the resonating member 130, the entire region except for a release hole for forming the cavity C may be used as a support layer, thereby securing structural robustness.

In addition, since resistance of the electrode connecting part is reduced and the heat radiation is improved, insertion lose by the electrical loss may be reduced, and interband notch failure, which may be caused by a temperature difference due to a difference in power consumption between bulk acoustic wave resonators 200 in a filter device, may also be controlled.

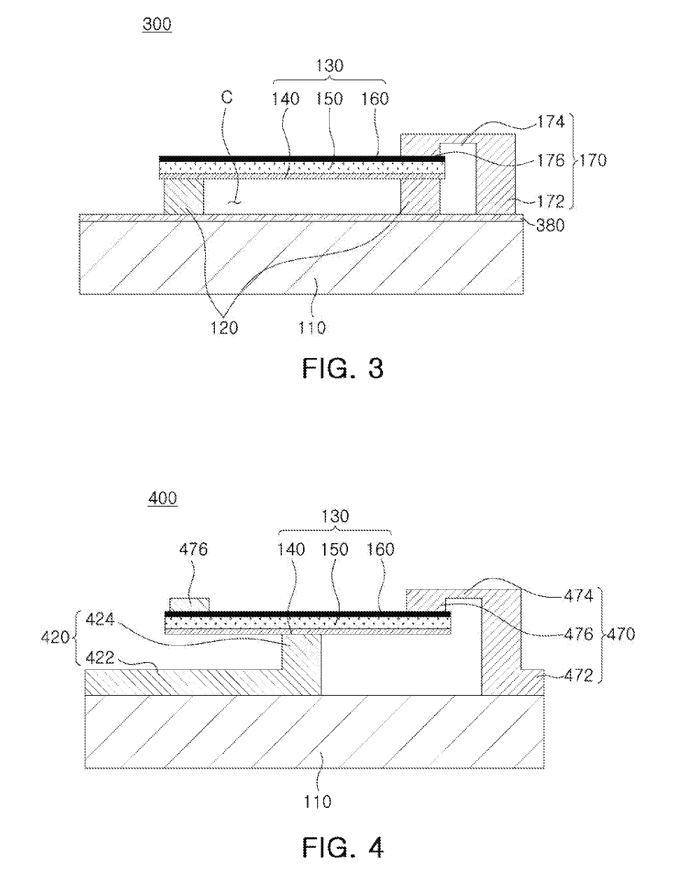

FIG. 3 is a schematic configuration view illustrating a bulk acoustic wave resonator 300, according to another embodiment.

Referring to FIG. 3, the bulk acoustic wave resonator 300 includes, for example, the substrate 110, the lower electrode connecting members 120, the resonating member 130, the upper electrode connecting member 170, and a reflective layer 380.

Since the substrate 110, the lower electrode connecting members 120, the resonating member 130, and the upper electrode connecting member 170 are the same components as the corresponding components included in the bulk acoustic wave resonator 100, a detailed description of the substrate 110, the lower electrode connecting members 120, the resonating member 130, and the upper electrode connecting member 170 will be omitted and will be replaced with the description above.

The reflective layer 380 may be formed on the substrate 110, and the lower electrode connecting members 120 and the upper electrode connecting member 170 may be formed on the reflective layer 380. The reflective layer 380 prevents vibrations (or resonance energy) generated by the resonating member 130 from being transferred to the substrate 110.

In other words, a portion of the resonating member 130 is disposed on the lower electrode connecting members 120 connected to the substrate 110. Therefore, the vibrations (or resonance energy) may be leaked into the substrate 110 through the lower electrode connecting members 120. In order to prevent loss due to such vibration leakage, the reflective layer 380 is formed on the substrate 110, thereby preventing deterioration of performance.

FIG. 4 is a schematic configuration view illustrating a bulk acoustic wave resonator 400, according to another embodiment.

Referring to FIG. 4, a bulk acoustic wave resonator 400 includes, for example, the substrate 110, a lower electrode connecting member 420, the resonating member 130, and an upper electrode connecting member 470.

Since the substrate 110 and the resonating member 130 are the same components as the corresponding components included in the bulk acoustic wave resonator 100, a detailed description of the substrate 110 and the resonating member 130 will be omitted and will be replaced with the description above.

The lower electrode connecting member 420 is connected to the substrate 110 and supports a central portion of the resonating member 130. As an example, the lower electrode connecting member 420 includes a base part 422 disposed on the substrate 110 and a support part 424 extended upwardly from the base part 422 and supporting the resonating member 130.

In addition, the support part 424 supports the central portion of the lower electrode 140. That is, the support part 424 is connected to the central portion of the lower electrode 140. In addition, the lower electrode connecting member 420 electrically connects the lower electrode 140 to the substrate 110. As an example, the lower electrode connecting member 420 is formed of a conductive material such as copper (Cu) or tungsten (W).

Thus, the lower electrode connecting member 420 supports the central portion of the resonating member 130, thereby further improving structural robustness and preventing stiction between the resonating member 130 and the substrate 110, which may occur at the time of resonance.

The upper electrode connecting member 470 is formed on the substrate 110 and one end portion of the upper electrode connecting member 470 is connected to the upper electrode 160. As an example, the upper electrode connecting member 470 includes an anchor member 472 formed on the substrate 110, a plate member 474 extended from the anchor member 472 to be parallel to the top surface of the substrate 110, and a connecting part 476 extended from an end of the plate member 474 to the upper electrode 160 and connected to the upper electrode 160.

In addition, the anchor member 472 is formed on the substrate 110 to be spaced apart from the lower electrode connecting member 420, on the substrate 110.

The connecting part 476 is connected to an edge of the upper electrode 160. As an example, the connecting part 476 has an amorphous ring shape. The upper electrode connecting member 470 is formed of a conductive material such as copper (Cu) or tungsten (W), similarly to the lower electrode connecting member 420.

As described above, the substrate 110 and the resonating member 130 are electrically connected to each other through the lower electrode connecting member 420 and the upper electrode connecting member 470. Accordingly, since the electrode connecting parts connecting the resonating member 130 are disposed on different planes, a gap between bulk acoustic wave resonators 400 in a filter device may be reduced, so a size of the filter device may also be reduced.

In addition, the lower electrode connecting member 420 supports the central portion of the resonating member 130, thereby further improving structural robustness and preventing stiction between the resonating member 130 and the substrate 110, which may occur at the time of resonance.

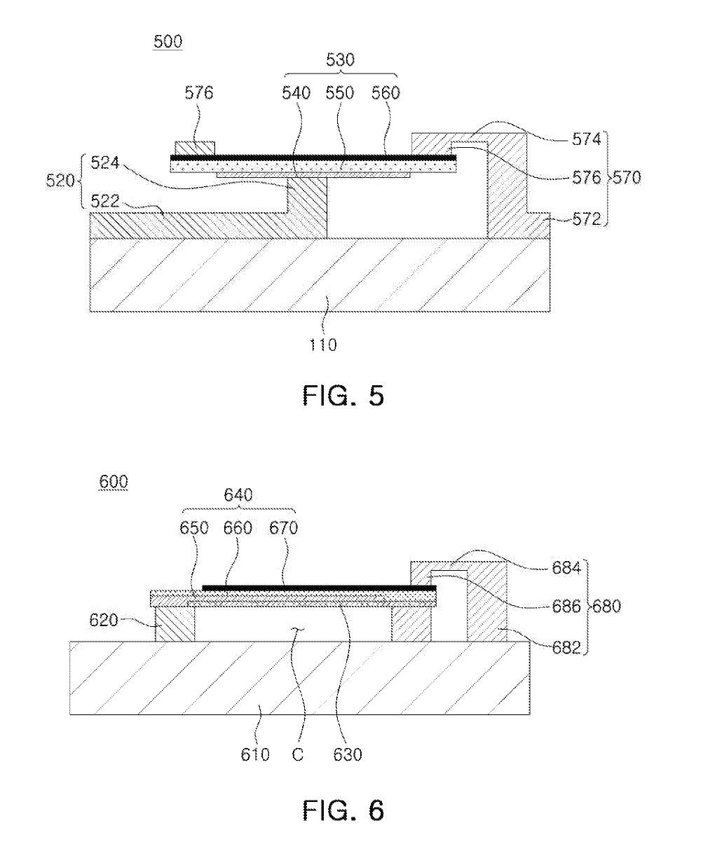

FIG. 5 is a schematic configuration view illustrating a bulk acoustic wave resonator 500, according to another embodiment.

Referring to FIG. 5, the bulk acoustic wave resonator 500 includes, for example, the substrate 110, a lower electrode connecting member 520, a resonating member 530, and an upper electrode connecting member 570.

Since the substrate 110 is the same component as the substrate included in the bulk acoustic wave resonator 100, a detailed description of the substrate 110 will be omitted and will be replaced with the description above.

The lower electrode connecting member 520 is connected to the substrate 110 and supports a central portion of the resonating member 530. As an example, the lower electrode connecting member 520 includes a base part 522 and a support part 524 extended upwardly from the base part 522 and supporting the resonating member 530.

The support part 524 supports the central portion of the lower electrode 540. That is, the support part 524 is connected to the central portion of the lower electrode 540.

In addition, the lower electrode connecting member 520 electrically connects the lower electrode 540 to the substrate 110. As an example, the lower electrode connecting member 520 is formed of a conductive material such as copper (Cu) or tungsten (W).

Thus, the lower electrode connecting member 520 supports the central portion of the resonating member 530, thereby further improving structural robustness and preventing stiction between the resonating member 530 and the substrate 110, which may occur at the time of resonance.

The resonating member 530 is disposed on the lower electrode connecting member 520. As an example, the resonating member 530 includes a lower electrode 540, a piezoelectric layer 550, and an upper electrode 560.

As an example, the lower electrode 540 has an area that is smaller than an area of the piezoelectric layer 550. In other words, the lower electrode 540 is formed so that edges of a bottom surface of the piezoelectric layer 550 are externally exposed.

The upper electrode connecting member 570 is formed on the substrate 110 and one end portion of the upper electrode connecting member 570 is connected to the upper electrode 560. As an example, the upper electrode connecting member 570 includes an anchor member 572 formed on the substrate 110, a plate member 574 extended from the anchor member 572 to be parallel to the top surface of the substrate 110, and a connecting part 576 extended from an end of the plate member 574 to the upper electrode 560 and connected to the upper electrode 560.

In addition, the anchor member 572 is formed on the substrate 110 to be disposed to be spaced apart from the lower electrode connecting member 520.

The connecting part 576 is connected to an edge of the upper electrode 560. As an example, the connecting part 576 has an amorphous ring shape. The upper electrode connecting member 570 is formed of a conductive material such as copper (Cu) or tungsten (W), similarly to the lower electrode connecting member 520.

FIG. 6 is a schematic configuration view illustrating a bulk acoustic wave resonator 600, according to another embodiment.

Referring to FIG. 6, the bulk acoustic wave resonator 600 includes, for example, a substrate 610, lower electrode connecting members 620, a membrane layer 630, a resonating layer 640, and an upper electrode connecting member 680.

The substrate 610 may be a substrate on which silicon is stacked. For example, a silicon wafer is used as the substrate 610. Meanwhile, a substrate protective layer (not shown) may be formed on the substrate 610.

The lower electrode connecting members 620 are formed on the substrate 610 and form a cavity C together with the resonating member 640. The lower electrode connecting members 620 are disposed to support edges of the resonating member 630. As an example, the lower electrode connecting members 620 have, for example, an amorphous ring shape corresponding to a shape of the resonating member 640.

Accordingly, since the lower electrode connecting members 620 support the entire region of the edges of the resonating member 640, structural robustness of the bulk acoustic wave resonator 600 may be provided.

The lower electrode connecting members 620 electrically connect a lower electrode 650 of the resonating member 640, to be described below, to the substrate 610. The lower electrode connecting members 620 are formed of a conductive material such as copper (Cu) or tungsten (W).

Thus, since the lower electrode connecting members 620 support the entire region of the edges of the resonating member 640, resistance of an electrode connecting part may be reduced and heat radiation may be improved. As a result, insertion loss due to electrical loss may be reduced and interband notch failure, which may be caused by a temperature difference due to a difference in power consumption between bulk acoustic wave resonators 600 in a filter device, may also be controlled.

The membrane layer 630 forms the cavity C together with the lower electrode connecting members 620. The membrane layer 630 is not be formed on a portion of the lower electrode connecting members 620 and covers the cavity C. As an example, the membrane layer 630 is formed of a material that is not damaged by halide based etching gas, such as silicon oxide (SiO₂) or aluminum nitride (AlN).

The resonating member 640 is disposed on the membrane layer 630. As an example, the resonating member 640 includes a lower electrode 650, a piezoelectric layer 660, and an upper electrode 670.

The lower electrode 650 is formed on the membrane layer 630 and is connected to a portion of the lower electrode connecting member 620. In addition, the lower electrode 650 is disposed over the cavity C. As an example, the lower electrode 650 is formed of a conductive material such as molybdenum (Mo), ruthenium (Ru), tungsten (W), iridium (Ir), or platinum (Pt), or alloys thereof.

The piezoelectric layer 660 covers the lower electrode 650 and the membrane layer 620. The piezoelectric layer 650 is formed by depositing, for example, aluminum nitride, doped aluminum nitride, zinc oxide, or lead zirconate titanate.

In addition, the piezoelectric layer 660, when formed of aluminum nitride (AlN), may further include a rare earth metal. As an example, the rare earth metal includes any one or any combination of any two or more of scandium (Sc), erbium (Er), yttrium (Y), and lanthanum (La). In addition, the piezoelectric layer 660, when formed of aluminum nitride (AlN), may further include a transition metal. As an example, the transition metal includes any one or any combination of any two or more of zirconium (Zr), titanium (Ti), magnesium (Mg), and hafnium (Hf).

Further, a portion of the piezoelectric layer 660 is externally exposed. In other words, the upper electrode 670 is not formed on a top surface of the externally exposed portion of the piezoelectric layer 660.

The upper electrode 670 is formed on the piezoelectric layer 660. As an example, the upper electrode 670 is also formed of a conductive material such as molybdenum (Mo), ruthenium (Ru), tungsten (W), iridium (Ir), or platinum (Pt), or alloys thereof, similarly to the lower electrode 650.

The upper electrode 670 is formed on the piezoelectric layer 660 to be disposed over the cavity C. Further, the upper electrode 670 is formed so that the portion of the piezoelectric layer 660 is externally exposed.

The upper electrode connecting member 680 is formed on the substrate 610 and one end portion of the upper electrode connecting member 680 is connected to the upper electrode 670. As an example, the upper electrode connecting member 680 includes an anchor member 682 formed on the substrate 610, a plate member 684 extended from the anchor member 682 to be parallel to the top surface of the substrate 110, and a connecting part 686 extended from an end of the plate member 684 to the upper electrode 670 and connected to the upper electrode 670.

In addition, the anchor member 682 is formed on the substrate 610 to be spaced apart from the lower electrode connecting members 620, on the substrate 610.

The connecting part 686 is connected to only an edge of the upper electrode 670. As an example, the upper electrode connecting member 680 is formed of a conductive material such as copper (Cu) or tungsten (W), similarly to the lower electrode connecting members 620.

As described above, since the lower electrode 650 and the upper electrode 670 are connected to the substrate 610 through the lower electrode connecting members 620 and the upper electrode connecting member 680, respectively, a gap between bulk acoustic wave resonators 600 in a filter device may be reduced, so that a size of the filter device may also be reduced.

Further, since the lower electrode connecting members 620 are disposed to support the entire region of the edge of the resonating member 640, the entire region except for a release hole for forming the cavity C may be used as a support layer, thereby providing the structural robustness.

In addition, since resistance of the electrode connecting part is reduced and heat radiation is improved, insertion loss by electrical loss may be reduced, and interband notch failure, which may be caused by the temperature difference due to a difference in power consumption between bulk acoustic wave resonators 600 in a filter device, may also be controlled.

FIG. 7 is a schematic configuration view illustrating a bulk acoustic wave resonator 700, according to another embodiment.

Referring to FIG. 7, the bulk acoustic wave resonator 700 includes, for example, the substrate 610, the lower electrode connecting members 620, the membrane layer 630, the resonating layer 640, and an upper electrode connecting member 780.

Since the substrate 610, the lower electrode connecting members 620, the membrane layer 630, and the resonating member 640 are the same components as the corresponding components included in the bulk acoustic wave resonator 600, a detailed description of the substrate 610, the lower electrode connecting members 620, the membrane layer 630, and the resonating member 640 will be omitted and will be replaced with the description above.

The upper electrode connecting member 780 is formed on the substrate 610 and one end portion of the upper electrode connecting member 780 is connected to the upper electrode 670. As an example, the upper electrode connecting member 780 includes an anchor member 782 formed on the substrate 610, a plate member 784 extended from the anchor member 782 to be parallel to the top surface of the substrate 610, and a connecting part 786 extended from an end of the plate member 784 to the upper electrode 670 and connected to the upper electrode 670.

The connecting part 786 is connected to an edge of the upper electrode 670. As an example, the connecting part 786 has a shape corresponding to a shape of the lower electrode connecting members 620, and has, an amorphous ring shape.

The upper electrode connecting member 780 is formed of a material such as copper (Cu) or tungsten (W), similarly to the lower electrode connecting members 620.

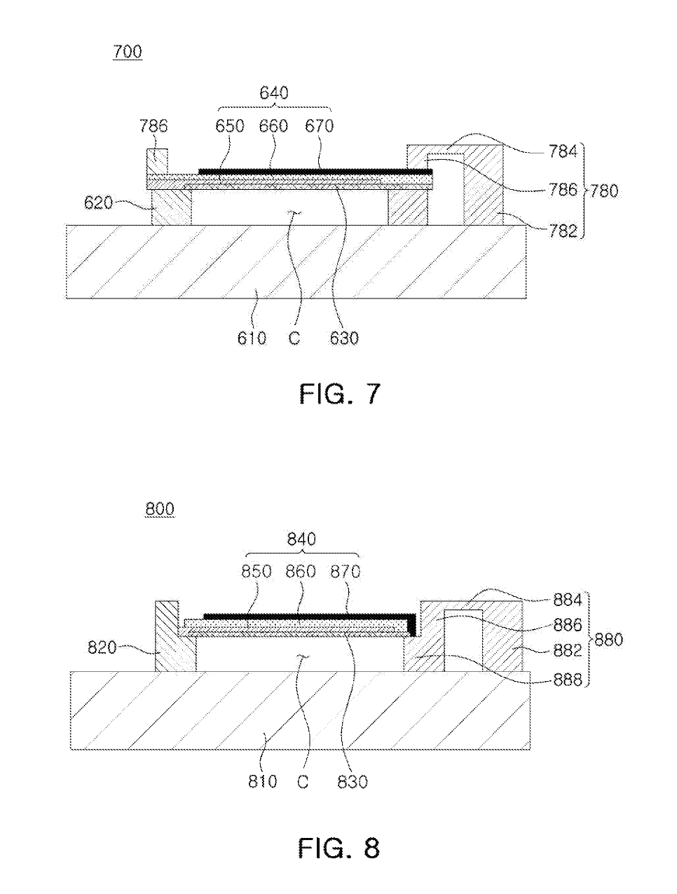

FIG. 8 is a schematic configuration view illustrating a bulk acoustic wave resonator 800, according to another embodiment.

Referring to FIG. 8, the bulk acoustic wave resonator 800 includes, for example, the substrate 610, a lower electrode connecting member 820, a membrane layer 830, a resonating member 840, and an upper electrode connecting member 880.

Since the substrate 610 is the same component as the substrate included in the bulk acoustic wave resonator 600, a detailed description of the substrate 610 will be omitted and will be replaced with the description above.

The lower electrode connecting member 820 is formed on the substrate 610 to support a portion of an edge of the resonating member 840 and is electrically connected to a lower electrode 850 of the resonating member 840. As an example, the lower electrode connecting member 820 is formed of a conductive material such as copper (Cu) or tungsten (W).

Further, the lower electrode connecting member 820 has an upper end portion which is stepped, thereby supporting the portion of the edge of the resonating member 840.

The membrane layer 830 forms a cavity C together with the lower electrode connecting member 820 and the upper electrode connecting member 880. The membrane layer 830 is formed so that edges thereof are supported by the lower electrode connecting member 820 and the upper electrode connecting member 880. As an example, the membrane layer 830 is formed of a material which is not damaged by halide based etching gas, such as silicon oxide (SiO₂) or aluminum nitride (AlN).

The resonating member 840 is disposed on the membrane layer 830. As an example, the resonating member 840 includes a lower electrode 850, a piezoelectric layer 860, and an upper electrode 870.

The lower electrode 850 is formed on the membrane layer 830 to be connected to the lower electrode connecting member 820. In addition, the lower electrode 850 is disposed over the cavity C. As an example, the lower electrode 650 is formed of a conductive material such as molybdenum (Mo), ruthenium (Ru), tungsten (W), iridium (Ir), or platinum (Pt), or alloys thereof.

The piezoelectric layer 860 covers the lower electrode 850 and the membrane layer 830. In addition, one side of the piezoelectric layer 860 is disposed on the same plane as one side of the membrane layer 830.

The piezoelectric layer 860 is formed by depositing, for example, aluminum nitride, doped aluminum nitride, zinc oxide, or lead zirconate titanate.

In addition, the piezoelectric layer 860, when formed of aluminum nitride (AlN), may further include a rare earth metal. As an example, the rare earth metal includes any one or any combination of any two or more of scandium (Sc), erbium (Er), yttrium (Y), and lanthanum (La). In addition, the piezoelectric layer 860, when formed of aluminum nitride (AlN), may further includes a transition metal. As an example, the transition metal includes any one or any combination of any two or more of zirconium (Zr), titanium (Ti), magnesium (Mg), and hafnium (Hf).

Further, a portion of the piezoelectric layer 860 is externally exposed. In other words, the upper electrode 870 is not formed on a top surface of the exposed portion of the piezoelectric layer 860.

The upper electrode 870 is formed on the piezoelectric layer 860. As an example, the upper electrode 870 is also formed of a conductive material such as molybdenum (Mo), ruthenium (Ru), tungsten (W), iridium (Ir), or platinum (Pt), or alloys thereof, similarly to the lower electrode 850.

The upper electrode 870 is formed on the piezoelectric layer 860 and is disposed over the cavity C. Further, the upper electrode 870 is formed so that the exposed portion of the piezoelectric layer 860 is externally exposed. In addition, a portion of the upper electrode 870 surrounds a side of the piezoelectric layer 860.

The upper electrode connecting member 880 is formed on the substrate 610 and one end portion of the upper electrode connecting member 880 is connected to the upper electrode 870. As an example, the upper electrode connecting member 880 includes a first anchor member 882 formed on the substrate 610, a plate member 884 extended from the first anchor member 882 to be parallel to the top surface of the substrate 610, a connecting part 886 extended downwardly from an end of the plate member 884, and a second anchor member 888 supporting a portion of the edge of the resonating member 840.

The upper electrode 870 and the connecting part 886 are connected to the second anchor member 888 and are electrically connected to each other.

As an example, the upper electrode connecting member 880 is formed of a conductive material such as copper (Cu) or tungsten (W), similarly to the lower electrode connecting member 820.

As described above, the resonating member 840 is disposed inside the lower electrode connecting member 820 and the second anchor member 888 of the upper electrode connecting member 880, whereby resonance energy leaked through the substrate 610 may be reduced.

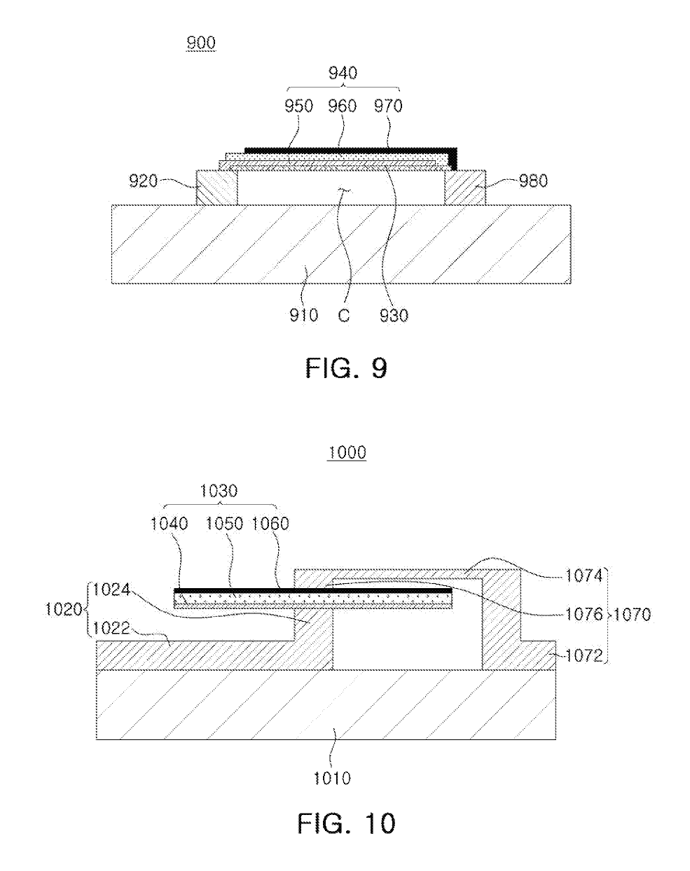

FIG. 9 is a schematic configuration view illustrating a bulk acoustic wave resonator 900, according to another embodiment.

Referring to FIG. 9, a bulk acoustic wave resonator 900 includes, for example, the substrate 610, a lower electrode connecting member 920, a membrane layer 930, a resonating layer 940, and an upper electrode connecting member 980.

Meanwhile, since the substrate 610 is the same component as the substrate included in the bulk acoustic wave resonator 600, a detailed description of the substrate 610 will be omitted and will be replaced with the description above.

The lower electrode connecting member 920 is formed on the substrate 610 to support a portion of an edge of the resonating member 940 and is electrically connected to a lower electrode 950 of the resonating member 940. As an example, the lower electrode connecting member 920 is formed of a conductive material such as copper (Cu) or tungsten (W).

The membrane layer 930 forms a cavity C together with the lower electrode connecting member 920 and the upper electrode connecting member 980. The membrane layer 930 is formed so that edges thereof are supported by the lower electrode connecting member 920 and the upper electrode connecting member 980. As an example, the membrane layer 930 is formed of a material which is not damaged by halide based etching gas, such as silicon oxide (SiO₂) or aluminum nitride (AlN).

The resonating member 940 is disposed on the membrane layer 930. As an example, the resonating member 940 includes the lower electrode 950, a piezoelectric layer 960, and an upper electrode 970.

The lower electrode 950 is formed on the membrane layer 930 and is connected to the lower electrode connecting member 920. In addition, the lower electrode 950 is disposed over the cavity C. As an example, the lower electrode 950 is formed of a conductive material such as molybdenum (Mo), ruthenium (Ru), tungsten (W), iridium (Ir), or platinum (Pt), or alloys thereof.

The piezoelectric layer 960 covers the lower electrode 950 and the membrane layer 930. In addition, one side of the piezoelectric layer 960 is disposed on the same plane as one side of the membrane layer 930.

The piezoelectric layer 960 is formed by depositing, for example, aluminum nitride, doped aluminum nitride, zinc oxide, or lead zirconate titanate.

In addition, the piezoelectric layer 960, when formed of aluminum nitride (AlN), may further include a rare earth metal. As an example, the rare earth metal includes any one or any combination of any two or more of scandium (Sc), erbium (Er), yttrium (Y), and lanthanum (La). In addition, the piezoelectric layer 960, when formed of aluminum nitride (AlN), may further include a transition metal. As an example, the transition metal includes any one or any combination of any two or more of zirconium (Zr), titanium (Ti), magnesium (Mg), and hafnium (Hf).

Further, a portion of the piezoelectric layer 960 is externally exposed. In other words, the upper electrode 970 is not formed on a top surface of the exposed portion of the piezoelectric layer 960.

The upper electrode 970 is formed on the piezoelectric layer 960. As an example, the upper electrode 970 is also formed of a conductive material such as molybdenum (Mo), ruthenium (Ru), tungsten (W), iridium (Ir), or platinum (Pt), or alloys thereof, similarly to the lower electrode 950.

The upper electrode 970 is formed on the piezoelectric layer 960 and is disposed over the cavity C. Further, the upper electrode 970 is formed so that the exposed portion of the piezoelectric layer 960 is externally exposed. In addition, a portion of the upper electrode 970 surrounds a side of the piezoelectric layer 960.

The upper electrode connecting member 980 is formed on the substrate 610 and one end portion the upper electrode connecting member 980 is connected to the upper electrode 970. In addition, the upper electrode connecting member 980 supports the resonating member 940 together with the lower electrode connecting member 920.

That is, the above-mentioned cavity C is formed by the upper electrode connecting member 980, the lower electrode connecting member 920, and the membrane layer 930.

As an example, the upper electrode connecting member 980 is formed of a conductive material such as a copper (Cu) or tungsten (W) material, similarly to the lower electrode connecting member 920.

As described above, the resonating member 940 is disposed inside the lower electrode connecting member 920 and the upper electrode connecting member 980, whereby resonance energy leaked through the substrate 610 may be reduced.

FIG. 10 is a schematic configuration view illustrating a bulk acoustic wave resonator 1000, according to another embodiment.

Referring to FIG. 10, the bulk acoustic wave resonator 1000 includes, for example, a substrate 1010, a lower electrode connecting member 1020, a resonating member 1030, and an upper electrode connecting member 1070.

The substrate 1010 may be a substrate on which silicon is stacked. For example, a silicon wafer is used as the substrate 1010. A substrate protective layer (not shown) may be formed on the substrate 1010.

The lower electrode connecting member 1020 is formed on the substrate 1010. The lower electrode connecting member 1020 is electrically connected to a lower electrode 1040 of the resonating member 1030. As an example, the lower electrode connecting member 1020 includes a base part 1022 and a support part 1024 extended from the base part 1022. The support part 1024 is extended to support a central portion of the lower electrode 1040.

In addition, the lower electrode connecting member 1020 is formed of a conductive material such as copper (Cu) or tungsten (W), for example.

As such, the lower electrode connecting member 1020 supports the central portion of the resonating member 1030, thereby further improving structural robustness and preventing stiction between the resonating member 1030 and the substrate 1010, which may occur at the time of resonance.

The resonating member 1030 is disposed on the lower electrode connecting member 1020. As an example, the resonating member 1030 includes a lower electrode 1040, a piezoelectric layer 1050, and an upper electrode 1060. In addition, the lower electrode 1040 is formed so that the central portion thereof is supported by the support part 1024 of the lower electrode connecting member 1020. That is, the support part 1024 is connected to the central portion of the lower electrode 1040. In addition, the piezoelectric layer 1050 is formed on a top surface of the lower electrode 1040. Further, the upper electrode 1060 is formed on a top surface of the piezoelectric layer 1050.

The upper electrode connecting member 1070 is formed on the substrate 1010 and one end portion of the upper electrode connecting member 1070 is connected to the upper electrode 1060. As an example, the upper electrode connecting member 1070 includes an anchor member 1072 formed on the substrate 1010, a plate member 1074 extended from the anchor member 1072 to be parallel to a top surface of the substrate 1010, and a connecting part 1076 extended from an end of the plate member 1074 and connected to the upper electrode 1060.

The connecting part 1076 is connected to the upper electrode 1060 at a central portion of the upper electrode 1060. That is, the lower electrode connecting member 1020 is connected to a bottom surface of the resonating member 1030, and the upper electrode connecting member 1070 is connected to a top surface of the resonating member 1030.

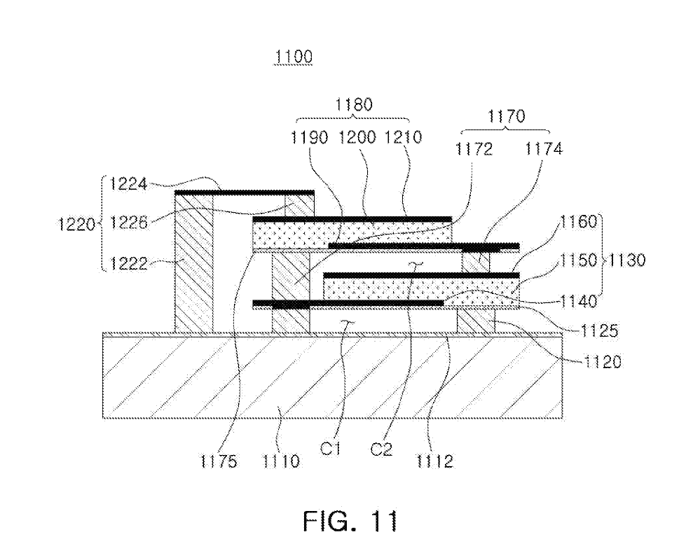

FIG. 11 is a schematic configuration view illustrating a bulk acoustic wave resonator 1100, according to another embodiment.

Referring to FIG. 11, a bulk acoustic wave resonator 1100 includes, for example, a substrate 1110, lower electrode connecting members 1120, a first resonating member 1130, a resonating member connecting member 1170, a second resonating member 1180, and an upper electrode connecting member 1220.

The substrate 1110 may be a substrate on which silicon is stacked. For example, a silicon wafer is used as the substrate 1110. Meanwhile, a substrate protective layer 1112 may be provided on the substrate 1110.

The lower electrode connecting members 1120 form a first cavity C1 together with a first membrane layer 1125 and the substrate 1110, and support the first resonating member 1130. The lower electrode connecting members 1120 are electrically connected to a first lower electrode 1140 of the first resonating member 1130.

As an example, the lower electrode connecting members 1120 are formed of a conductive material such as copper (Cu) or tungsten (W).

The first resonating member 1130 is disposed on the lower electrode connecting members 1120. The first resonating member 1130 includes the first lower electrode 1140, a first piezoelectric layer 1150, and a first upper electrode 1160.

As an example, the first lower electrode 1140 is extended to protrude from the first piezoelectric layer 1150 and is disposed on the first membrane layer 1125.

The resonating member connecting member 1170 is formed on the first resonating member 1130. The resonating member connecting member 1170 includes a first resonating member connecting member 1172 extended from the first lower electrode 1140 and a second resonating member connecting member 1174 extended from the first upper electrode 1160.

A top surface of the first resonating member connecting member 1172 is connected to a second membrane layer 1175, and a top surface of the second resonating member connecting member 1174 is connected to a second lower electrode 1190 of the second resonating member 1180.

The first resonating member connecting member 1172 and the second resonating member connecting member 1174 form a second cavity C2 together with the second membrane layer 1175 and the first resonating member 1130.

The second resonating member 1180 is disposed on the first resonating member 1130 while being formed on the second membrane layer 1175.

The second resonating member 1180 includes a second lower electrode 1190, a second piezoelectric layer 1200, and a second upper electrode 1210. As an example, the second lower electrode 1190 is extended to protrude from the second piezoelectric layer 1200 and is disposed on the second membrane layer 1175.

The upper electrode connecting member 1220 is formed on the substrate 1110 and is connected to the second upper electrode 1210 of the second resonating member 1180. As an example, the upper electrode connecting member 1220 includes an anchor member 1222 formed on the substrate 1110, a plate member 1224 extended from the anchor member 1222, and a connecting part 1226 extended from the plate member 1224 and connected to the second upper electrode 1210.

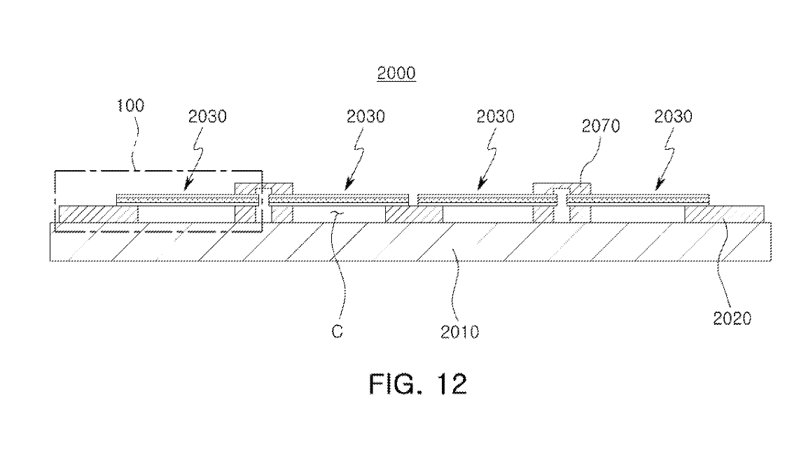

FIG. 12 is a schematic configuration view illustrating a filter device 2000, according to an embodiment.

Referring to FIG. 12, the filter device 2000 includes, for example bulk acoustic wave resonators 100. That is, resonating members 2030 are connected to a substrate 2010.

The resonating members 2030 are supported by lower electrode connecting members 2020 and upper electrode connecting members 2070, and cavities C are formed below the plurality of resonating member 2030.

As such, the resonating members 2030 are electrically connected to the substrate 2010 through the lower electrode connecting members 2020 and the upper electrode connecting members 2070. Further, the bulk acoustic wave resonators 100, which are disposed to be adjacent to each other, are electrically connected to each other through the lower electrode connecting members 2020 and the upper electrode connecting members 2070.

Therefore, since the lower electrode connecting members 2020 and the upper electrode connecting members 2070 are connected to the resonating members 2030 on different planes, various connection methods may be adopted.

Accordingly, the filter device 2000 may reduce an area occupied by the bulk acoustic wave resonators 100, thereby reducing a size of the filter device 2000.

Hereinafter, a method for manufacturing a bulk acoustic wave resonator 3000, according to an embodiment, will be described with reference to the accompanying drawings.

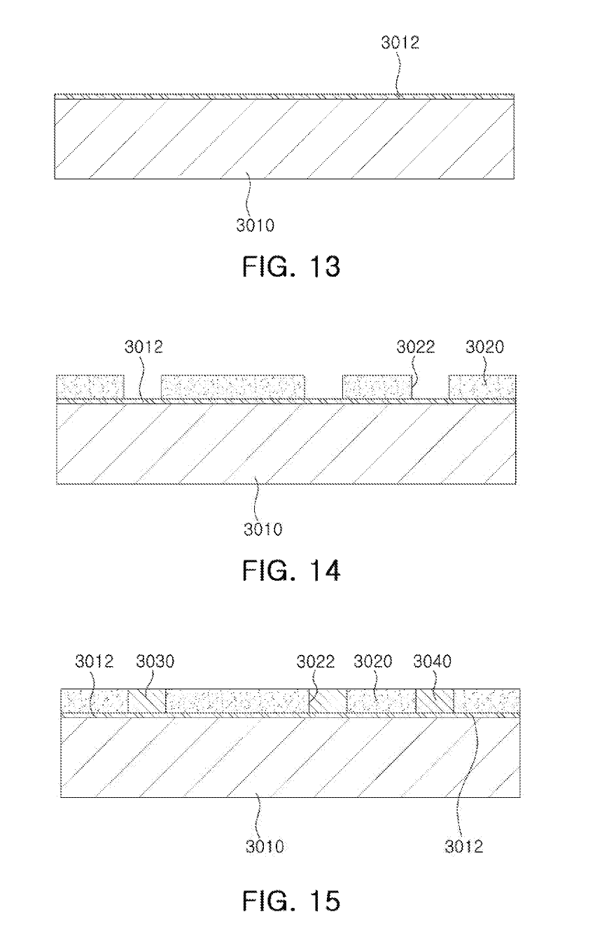

FIGS. 13 through 22 are process flowcharts illustrating a method for manufacturing the bulk acoustic wave resonator 3000, according to an embodiment.

First, as illustrated in FIG. 13, a substrate protective layer 3012 is formed on a substrate 3010. The substrate protective layer 3012 is formed of, for example, an aluminum nitride (AlN) material.

Next, as illustrated in FIG. 14, a sacrificial layer 3020 is formed on the substrate protective layer 3012. Groove parts 3022 for forming lower end portions of a lower electrode connecting member 3030 and an upper electrode connecting member 3040 to be described below are formed in the sacrificial layer 3020.

The sacrificial layer 3020 may be formed of a material containing silicon oxide (SiO₂) or polysilicon. In addition, the sacrificial layer 3020 is formed, for example, in a spin-on-glass operation. That is, the sacrificial layer 3020 may be formed by an operation of spin-coating and heat-treating silicon dissolved in an organic solvent to form a silicon oxide (SiO₂) insulating film.

Next, as illustrated in FIG. 15, the lower end portions of the lower electrode connecting member 3030 and the upper electrode connecting member 3040 to be described below are formed in the groove parts 3022 of the sacrificial layer 3020. As an example, the lower electrode connecting member 3030 and the upper electrode connecting member 3040 are formed of a conductive material such as copper (Cu) or tungsten (W). Next, a planarization task may be performed through a chemical mechanical polishing (CMP) operation, as needed. As an example, the planarization task is performed through a metal chemical mechanical polishing (CMP) operation.

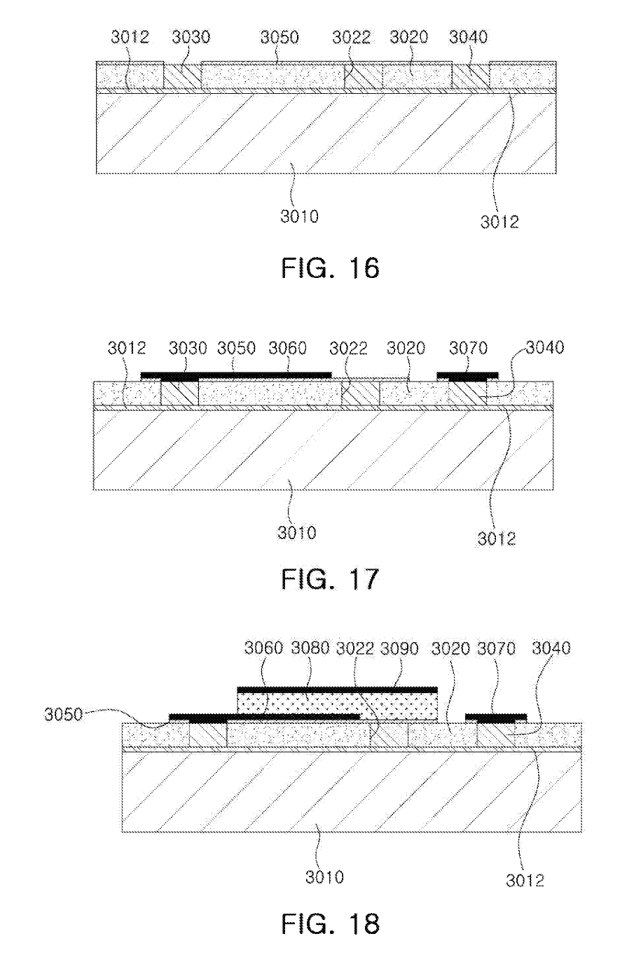

Next, as illustrated in FIG. 16, a seed layer 3050 is formed on a top surface of the sacrificial layer 3020. The seed layer 3050 is formed of, for example, an aluminum nitride (AlN) material. Exposure holes are formed in the seed layer 3050 so that the lower end portions of the lower electrode connecting member 3030 and the upper electrode connecting member 3040 are exposed externally.

Next, as illustrated in FIG. 17, a portion of the seed layer 3050 is removed by patterning, and a lower electrode 3060 is formed on a top surface of the seed layer 3050. Further, a connecting layer 3070 is also formed on a top surface of the lower end portion of the upper electrode connecting member 3040.

Next, as illustrated in FIG. 18, a piezoelectric layer 3080 and an upper electrode 3090 are sequentially formed.

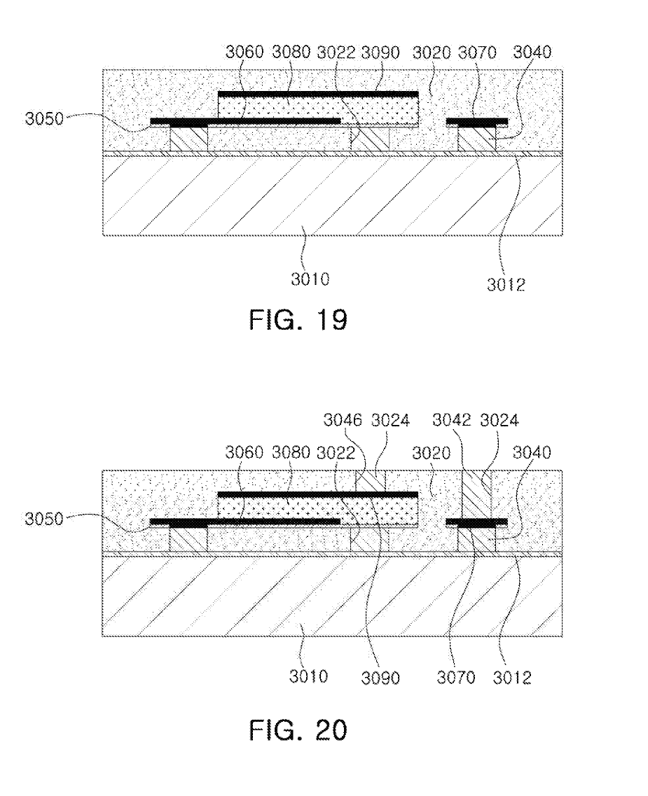

Next, as illustrated in FIG. 19, the sacrificial layer 3020 is further formed to bury the lower electrode 3060, the piezoelectric layer 3080, and the upper electrode 3070.

Next, as illustrated in FIG. 20, a formation hole 3024 for forming the upper electrode connecting member 3040 is formed in the sacrificial layer 3020 to form a portion of the upper electrode connecting member 3040. As an example, upper end portions of a connecting part 3046 and an anchor member 3042 of the upper electrode connecting member 3040 to be described below are formed.

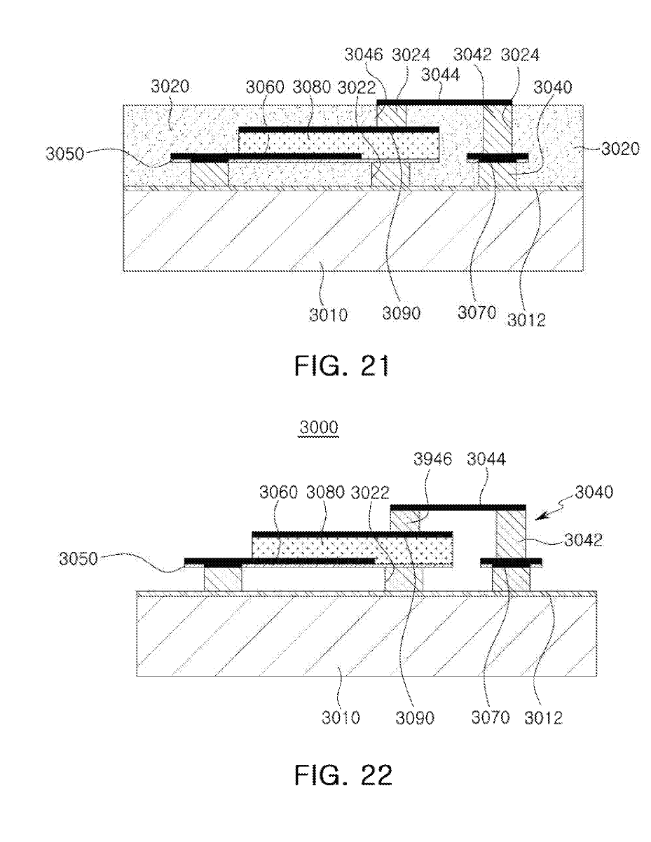

Next, as illustrated in FIG. 21, a plate member 3044 that connects the upper end portions of the connecting part 3046 and the anchor member 3042 with each other are formed on the top surface of the sacrificial layer 3020.

Next, as illustrated in FIG. 22, the sacrificial layer 3020 is removed by using halide based gas.

As set forth above, according to the embodiments disclosed herein, a bulk acoustic wave resonator may control notch failure while providing structural robustness and reducing insertion loss.

Further, the size of the filter device including the plurality of bulk acoustic wave resonators may be reduced.

While this disclosure includes specific examples, it will be apparent after an understanding of the disclosure of this application that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

What is claimed is:

1. A bulk acoustic wave resonator, comprising:
a substrate;
a lower electrode connecting member disposed on the substrate;
a resonating member comprising
a lower electrode disposed on the lower electrode connecting member,
a piezoelectric layer disposed on the lower electrode, and
an upper electrode disposed on the piezoelectric layer; and
an upper electrode connecting member electrically connecting the upper electrode and the substrate to each other,
wherein the upper electrode connecting member is extended from the substrate outside of the resonating member and is connected to a top surface of the upper electrode, and
wherein the lower electrode connecting member electrically connects the lower electrode and the substrate to each other and comprises a ring shape corresponding to a shape of the resonating member so as to support an edge of the resonating member.

2. The bulk acoustic wave resonator of claim 1, wherein the lower electrode connecting member is connected to a bottom surface of the lower electrode.

3. The bulk acoustic wave resonator of claim 1, wherein the upper electrode connecting member comprises
an anchor member disposed on the substrate,
a plate member extended from the anchor member, and
a connecting part disposed on the top surface of the upper electrode and connected to the plate member.

4. The bulk acoustic wave resonator of claim 3, wherein the connecting part is disposed on a portion of a region of an edge of the upper electrode.

5. The bulk acoustic wave resonator of claim 3, wherein the connecting part is disposed on an entire region of an edge of the upper electrode.

6. The bulk acoustic wave resonator of claim 3, wherein
the upper electrode has a size that is smaller than a size of the piezoelectric layer, and
the connecting part is connected to a portion of a region of an edge of the upper electrode and has the ring shape corresponding to the shape of the resonating member.

7. The bulk acoustic wave resonator of claim 1, further comprising:
a reflective layer disposed on a top surface of the substrate,
wherein the lower electrode connecting member and the upper electrode connecting member are disposed on the reflective layer.

8. The bulk acoustic wave resonator of claim 1, further comprising a membrane layer covering a cavity.

9. A bulk acoustic wave resonator, comprising:
a substrate;
a lower electrode connecting member disposed on the substrate;
a resonating member comprising
a lower electrode disposed on the lower electrode connecting member;
a piezoelectric layer disposed on the lower electrode, and
an upper electrode disposed on the piezoelectric layer; and
an upper electrode connecting member electrically connecting the upper electrode and the substrate to each other,
wherein the lower electrode connecting member electrically connects the lower electrode and the substrate to each other and forms a cavity between the resonating member and the substrate,
wherein the lower electrode connecting member supports a central portion of the resonating member, and
wherein the upper electrode connecting member is extended from the substrate outside of the resonating member and is connected to a top surface of the upper electrode.

10. The bulk acoustic wave resonator of claim 9, wherein the lower electrode connecting member comprises a base part disposed on the substrate, and a support part extended from the base part and connected to a bottom surface of the lower electrode.

11. The bulk acoustic wave resonator of claim 10, wherein the lower electrode is disposed on a central part of the piezoelectric layer.

12. The bulk acoustic wave resonator of claim 9, wherein the upper electrode connecting member is connected to a central portion of the upper electrode.

13. A bulk acoustic wave resonator, comprising:
a substrate;
a lower electrode connecting member disposed on the substrate;
a resonating member comprising
a lower electrode disposed on the lower electrode connecting member,
a piezoelectric layer disposed on the lower electrode, and
an upper electrode disposed on the piezoelectric layer; and
an upper electrode connecting member electrically connecting the upper electrode and the substrate to each other,
wherein the lower electrode connecting member electrically connects the substrate and the lower electrode to each other and supports a portion of an edge of the resonating member,
wherein the upper electrode connecting member is spaced apart from the lower electrode connecting member and supports another portion of the edge of the resonating member, and
wherein the lower electrode connecting member and the upper electrode connecting member form a cavity between the resonating member and the substrate.

14. The bulk acoustic wave resonator of claim 13, wherein the upper electrode comprises a connecting part connected to the upper electrode connecting member.

15. The bulk acoustic wave resonator of claim 13, further comprising a membrane layer formed to cover a cavity.

16. A bulk acoustic wave resonator, comprising:
a substrate;
a lower electrode connecting member disposed on the substrate;
a first resonating member disposed on the lower electrode connecting member;
a resonating member connecting member connected to the first resonating member;
a second resonating member connected to the first resonating member through the resonating member connecting member, and disposed on the first resonating member; and
an upper electrode connecting member electrically connecting the substrate and the second resonating member to each other.

17. The bulk acoustic wave resonator of claim 16, wherein
the first lower electrode is disposed on a first membrane layer, and
the lower electrode connecting member forms a first cavity together with the first membrane layer and the substrate.

18. The bulk acoustic wave resonator of claim 17, wherein
the second lower electrode is disposed on a second membrane layer, and
the resonating member connecting member forms a second cavity together with the second membrane layer.
